(19) United States
(12) Patent Application Publication
(10) Pub. No.: US 2021/0215763 A1
(43) Pub. Date: Jul. 15, 2021

(54) METHOD FOR IMPROVING ACCURACY OF CAPACITY MEASUREMENT

(71) Applicant: JIANGSU GAREA HEALTH TECHNOLOGY CO., LTD, Suzhou (CN)

(72) Inventors: Xiangbao TONG, Suzhou (CN); Xiaodong WANG, Suzhou (CN); Jisong HU, Suzhou (CN); Haofang YANG, Suzhou (CN)

(21) Appl. No.: 16/606,526

(22) PCT Filed: Jun. 10, 2019
(86) PCT No.: PCT/CN2019/090534

§ 371 Date: Oct. 18, 2019

(30) Foreign Application Priority Data
Aug. 27, 2018 (CN) 201810994557.X

(51) Int. Cl. G01R 31/36; G01R 31/3842

(52) U.S. Cl. CPC G01R 31/3648; G01R 31/3842

(57) ABSTRACT

The disclosure relates to a method for improving the accuracy of capacity measurement, including: determining an optimal state of capacity detection of a device; determining a current state of the device when a capacity detection cycle arrives; directly performing battery capacity detection if the current state is an optimal state, and finishing the capacity detection cycle upon completion of the detection; and if the current state is not an optimal state, executing the subsequent step; and storing related information about the current state of the device, switching the device to the optimal state, performing battery capacity detection on the device in the optimal state, and switching the device to a state prior to the detection upon completion of the detection.

### CROSS-REFERENCE TO RELATED APPLICATIONS

This application is a national stage application under 35 U.S.C. 371 of PCT Application No. PCT/CN2019/090534 having an international filing date 10 Jun. 2019, which PCT application claimed the benefit of CN Application No. 201810994557.X filed 27 Aug. 2018, the entire disclosure of each of which are hereby incorporated herein by reference.

### FIELD

The present disclosure relates to the field of battery detection, and in particular, to a method for improving the accuracy of capacity measurement.

### BACKGROUND

There is a requirement for battery capacity detection to battery-powered electronic devices on the market basically. In high-precision battery capacity detection a coulombmeter is basically adopted to monitor battery capacity consumption. However, this method is highly complex, so as to add an independent battery capacity detection chip to the device and to increase the cost greatly.

A method for judging the residual capacity by acquiring a battery voltage is relatively cheap and easy to implement, so it has become a popular choice for devices with low cost and low precision requirements. In this method, an algorithm can be easily implemented by code, on the basic of the conversion of the corresponding relationship between the battery voltage and the residual battery capacity. In practice, the corresponding residual battery voltage can be calculated only by obtaining a real-time battery voltage.

However, at present, the method for judging the residual capacity by acquiring a battery voltage is not very accurate and the measured value is not stable. Especially in the application where the load power consumption is constantly changing, the collected voltage of battery keeps jumping, which leads to a large fluctuation in the calculated value of the residual battery capacity, bringing great trouble to designers and users.

### SUMMARY

To solve the foregoing technical problem, a method for improving the accuracy of capacity measurement is provided.

In the present disclosure the following technical solutions are adopted.

A method for improving the accuracy of capacity measurement, including steps of:

(1) determining an optimal state of capacity detection of a device;

(2) determining a current state of the device when a capacity detection cycle arrives;

(3) performing battery capacity detection directly if the current state is an optimal state, and finishing the capacity detection cycle upon completion of the detection; and if the current state is not an optimal state, executing a subsequent step; and

(4) storing related information about the current state of the device, switching the device to the optimal state, performing battery capacity detection on the device in the optimal state, and switching the device back to the state prior to the detection upon completion of the detection.

Further, the optimal state is defined to be the most common working state of the device, that is, the time consumed by different working states in a past period of time is counted, and the working state with the largest proportion of the total time is selected as the optimal state.

Further, the steps of determining an optimal state are as follows.

(1) the device detecting and recording the voltage under the current state at a regular cycle time T;

(2) when the duration of the device in a state (excluding a sleep or shutdown state) exceeds a predetermined time threshold, after the end of the state, the device calculating a fluctuation index based on the voltage condition of the state during the duration, wherein a specific fluctuation index calculation method is as follows:

supposing a voltage sequence detected in the state during the period of time is V1, V2, . . . , Vm, calculating m−1 voltage drop rates Ai (2≤i≤m), respectively, by a formula of

$${A}_{i} = \frac{{V}_{1} - {V}_{i}}{( t - 1 ) T} ,$$

then calculating an average value A of the m−1 Ai, and the fluctuation index W, by a formula of

$$W = \frac{{\sum }_{i = 2}^{in} \vert A - {A}_{f} \vert}{m - 1} ;$$

(3) the device re-determining its optimal state at a specified moment, specifically, the device determining the total duration of each state (excluding a sleep or shutdown state) over a past period of time, and if the total duration of a state exceeds a predetermined threshold, taking it as a candidate state of the optimal state; calculating, for each candidate state, an average value of all fluctuation indexes thereof in the period of time, and determining the candidate state with the smallest average value as the optimal state.

Further, the device is a smart phone.

Further, the battery capacity detection is detecting a voltage and then obtaining a corresponding residual battery capacity by calculation according to a corresponding relationship between the voltage and the residual battery capacity.

Further, the detection of the voltage under the current state is synchronous with the capacity detection cycle.

Further, the specified moment is zero o'clock of each day.

Further, the period of time is one day.

The present disclosure has the following beneficial effects in that: an interval that leads to system voltage fluctuation is avoided, and an optimal working state for measuring capacity is selected to detect residual battery capacity, so as to effectively avoid inaccurate detection and fluctuation of residual battery capacity caused by power consumption fluctuation.

### BRIEF DESCRIPTION OF THE DRAWINGS

The accompanying drawings described here are used to provide further understanding of the present disclosure, but do not improperly limit the present disclosure. In the drawings,

FIG. 1 shows specific steps of a detection method according to the present disclosure.

### DETAILED DESCRIPTION

The present disclosure will be described in detail below with reference to the accompanying drawings and specific embodiments. Exemplary embodiments and descriptions are merely used to explain the present disclosure, but do not limit the present disclosure.

Similar to the prior art, the residual battery capacity is calculated through a battery voltage in the present disclosure. However, generally, a battery-powered electronic device (such as a smart phone) has a variety of working states. Under different working states, there are different power consumption requirements and different loads for the device, leading to large fluctuations in the system voltage. For example, when the device is switched from an idle state to a working state, the current increases, the system voltage is pulled down, and the residual battery capacity obtained by corresponding calculation drops significantly in an instant. Therefore, the residual battery capacity calculated and based on the voltage will also have a large fluctuation, which brings trouble to users.

In order to detect battery capacity from a voltage, it is necessary to determine in which state of the device the residual battery capacity is detected. Generally, the purpose of measuring battery capacity is to show a user how long the device can continue to work, so the capacity measurement should also be conducted when the device is working normally rather than sleeping or shutting down. However, even for the working state, the device may have a variety of possible working states, and it is still necessary to determine in which working state detection is performed, which is the so-called optimal working state for detecting capacity (referred to as an optimal state) in the present disclosure. According to an embodiment of the present disclosure, the optimal state may be simply selected as the most common working state of the device, that is, the time consumed by different working states in a past period of time is counted, and the working state with the largest proportion of the total time is selected as the optimal state.

After the optimal state is determined, the battery capacity can be detected. The battery capacity is detected periodically, for example, in each minute. Then, the device may not be in the optimal state during the detection, so the present disclosure proposes a method for detecting capacity by switching states.

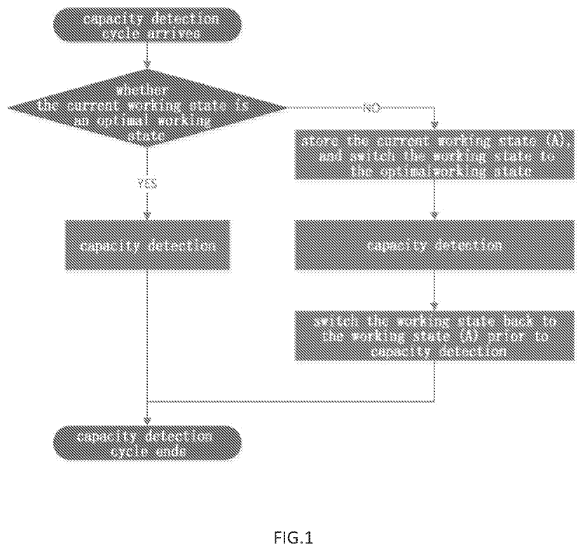

Specific steps of a detection method according to the present disclosure are shown with reference to FIG. 1 and described in detail as follows.

(1) A current state of the device is determined when a capacity detection cycle arrives.

As stated above, capacity detection is performed periodically. When the detection cycle arrives, the capacity detection is started. At this time, the device may be in various states, such as a sleep state, an idle state, a running state of high power consumption, a running state of low power consumption, and so on. Specific states can be pre-defined. For example, for a smartphone, various possible states can be pre-defined by mobile phone manufacturers.

(2) If the current state is an optimal state, the battery capacity detection is directly performed and the capacity detection cycle is ended upon completion of the detection; else if the current state is not an optimal state, a subsequent step is executed.

The specific battery capacity detection process here is similar to that in the prior art, that is, a voltage is detected and then a corresponding residual battery capacity is obtained by calculation according to a corresponding relationship between the voltage and the residual battery capacity. As the prior art, detailed description is omitted here.

(3) Related information about the current state of the device is stored, the device is switched to the optimal state, battery capacity detection is performed on the device in the optimal state, and the device is switched back to a state prior to the detection upon completion of the detection.

The related information about the current state can be a snapshot of the running state of the whole device. After detection, it can be quickly switched back to the original state according to the stored related information.

With the above method, an optimal working state for detecting capacity is selected to detect residual battery capacity, which can effectively avoid inaccurate detection and fluctuation of residual battery capacity caused by power consumption fluctuation. When the measurement cycle is not under the optimal state, reasonably switching the system working state to an optimal state for detection is an important mechanism to ensure the implementation of this method.

It can be seen from the above processes that the selection of the optimal state is a core of the present disclosure. According to an embodiment of the disclosure, the selection of the optimal state needs to consider not only the time proportion of the state, but also the voltage fluctuation under the state. If the voltage fluctuation of a state itself is relatively large, it is not suitable to serve as the optimal state. The method for selecting an optimal method in this embodiment is described in detail below.

(1) The device detects and records the voltage under the current state at a regular cycle time T. This step can be synchronous with the capacity detection cycle, that is, the two cycles are the same. The voltage under the current state is detected first, and then the capacity measurement step is executed.

(2) When the duration of the device in a state (excluding a sleep or shutdown state) exceeds a predetermined time threshold, after the end of the state, the device calculates a fluctuation index based on the voltage condition of the state during the duration, wherein a specific fluctuation index calculation process is as follows:

supposing a voltage sequence detected in the state during the period of time is V1, V2, . . . , Vm, calculating m−1 voltage drop rates Ai (2≤i≤m) respectively, by a formula of

Aᵢ=V₁−Vᵢ/(i−1)T

then calculating an average value A of the m−1 Ai, and the fluctuation index W by a formula of

$$W = \frac{{\sum }_{i = 2}^{in} \vert A - {A}_{f} \vert}{m - 1} ;$$

(3) The device re-determines its optimal state at a specified moment (the specified moment may be, for example, zero o'clock of each day), specifically, the device determines the total duration of each state (excluding a sleep or shutdown state) over a past period of time (e.g., within one day), and if the total duration of a state exceeds a predetermined threshold, takes it as a candidate state of the optimal state; calculates, for each candidate state, an average value of all fluctuation indexes thereof in the period of time, and determines the candidate state with the smallest average value as the optimal state.

For example, if in a state there are 10 durations that meet the requirements of step (2) within the time period, 10 fluctuation indexes will be calculated respectively, so that an average value of these 10 fluctuation indexes can be calculated.

Through the above processes, a common state with small voltage fluctuation is selected as the optimal state, thus improving the accuracy of capacity measurement.

The above only describes the preferred embodiments of the present disclosure. Thus, any equivalent variations or modifications made according to the structure, features and principles described in the scope of the disclosure are all fell into the scope limited by the claims appended hereto.

1. A method for improving the accuracy of capacity measurement, comprising:
determining an optimal state of capacity detection of a device;
determining a current state of the device when a capacity detection cycle arrives;
performing a battery capacity detection directly if the current state is an optimal state, and finishing the battery capacity detection cycle upon completion of the detection; and executing a subsequent step, if the current state is not an optimal state; and
storing related information with respect to the current state of the device, switching the device to the optimal state, performing battery capacity detection on the device in the optimal state, and switching the device back to a state prior to the detection upon completion of the detection.

2. The method of claim 1, wherein the optimal state is the most common working state of the device, that is, the time consumed by different working states in a past period of time is counted, and the working state with the largest proportion of the total time is selected as the optimal state.

3. The method of claim 1, wherein determining the optimal state comprising:
detecting and recording, by the device, the voltage under the current state at a regular cycle time T;
determining a duration of the device in a state (excluding a sleep or shutdown state) exceeding a predetermined time threshold, and after the end of the state, calculating, by the device, a fluctuation index based on the voltage condition of the state during the duration, wherein calculating a specific fluctuation index comprising:
supposing a voltage sequence detected in the state during the period of time is V₁, V₂, . . . , Vₘ, calculating m−1 voltage drop rates Aᵢ (2≤i≤m) respectively, by a formula of
$${A}_{i} = \frac{{V}_{1} - {V}_{i}}{( t - 1 ) T} ,$$
calculating an average value A of the m−1 Aᵢ, and the fluctuation index W, by a formula of
$$W = \frac{{\sum }_{i = 2}^{in} \vert A - {A}_{i} \vert}{m - 1} ;$$
re-determining, by the device, the optimal state at a specified moment, specifically, determining, by the device, the total duration of each state excluding a sleep or shutdown state over a past period of time, and if the total duration of a state exceeds a predetermined threshold, taking it as a candidate state of the optimal state; and
calculating, for each candidate state, an average value of all fluctuation indexes thereof in the period of time, and determining the candidate state with the smallest average value as the optimal state.

4. The method of claim 1, wherein the device is a smart phone.

5. The method of claim 1, wherein performing the battery capacity detection comprising detecting a voltage and then obtaining a corresponding residual battery capacity by calculation according to a corresponding relationship between the voltage and the residual battery capacity.

6. The method of claim 3, wherein the detecting the voltage under the current state is synchronous with the capacity detection cycle.

7. The method of claim 3, wherein the specified moment is zero o'clock of each day.

8. The method of claim 3, wherein the period of time is one day.

9. The method of claim 2, wherein performing the battery capacity detection comprising detecting a voltage and obtaining a corresponding residual battery capacity by calculation according to a corresponding relationship between the voltage and the residual battery capacity.

10. The method of claim 3, wherein performing the battery capacity detection comprising detecting a voltage and obtaining a corresponding residual battery capacity by calculation according to a corresponding relationship between the voltage and the residual battery capacity.

11. The method of claim 4, wherein performing the battery capacity detection comprising detecting a voltage and obtaining a corresponding residual battery capacity by calculation according to a corresponding relationship between the voltage and the residual battery capacity.
